(19) United States
(12) Patent Application Publication
(10) Pub. No.: US 2013/0043768 A1
(43) Pub. Date: Feb. 21, 2013

(54) ULTRASOUND TRANSDUCER ARRAY

(71) Applicants: Sandy Cochran, Dundee (GB); Christine Demore, Dundee (GB); Luis Garcia-Gancedo, Birmingham (GB); Timothy Button, Birmingham (GB); Jeff Bamber, London (GB)

(72) Inventors: Sandy Cochran, Dundee (GB); Christine Demore, Dundee (GB); Luis Garcia-Gancedo, Birmingham (GB); Timothy Button, Birmingham (GB); Jeff Bamber, London (GB)

(73) Assignees: UNIVERSITY OF BIRMINGHAM, Birmingham (GB); UNIVERSITY OF DUNDEE, Dundee (DE)

(21) Appl. No.: 13/497,193

(22) PCT Filed: Sep. 21, 2010
(86) PCT No.: PCT/GB2010/001765

§ 371 Date: Oct. 4, 2012

(30) Foreign Application Priority Data
Sep. 21, 2009 (GB) 0916427.8

(51) Int. Cl. H01L 41/04; H01L 41/24; H01L 41/22

(52) U.S. Cl. 310/334; 29/25.35

(57) ABSTRACT

An ultrasonic transducer array and method of making an ultrasonic transducer array. The array comprising a plurality of individual array elements made from a piezoelectric composite which is made from a plurality of individual piezoelectric segments; a passive filler between the piezoelectric segments; and, one or more electrodes for driving the array elements formed from the piezoelectric segments; wherein the spatial pattern of the piezoelectric segments of the piezoelectric composite defines one or more non-linear, irregular channels which separate the piezoelectric segments thereby minimising interaction between the individual array elements and minimising spurious modes in the ultrasound transducer array.

The present invention relates to an ultrasound transducer array and a method of making an ultrasound transducer array, in particular where the ultrasound transducer array is suitable for transmitting and/or receiving high frequency ultrasound signals.

### BACKGROUND TO THE INVENTION

Ultrasound transducer arrays such as those used for medical imaging with ultrasound at frequencies of 2-10 MHz for example, use arrays of individual piezoelectric elements, each of which are connected to pulsing-receiving circuitry and operate independently of other array elements. The array elements are typically made of piezoelectric ceramic or piezoelectric single crystal material. The array elements are designed to radiate ultrasound in a direction that is substantially perpendicular to the face of the transducer array. Ideally, the array elements are isolated electrically and acoustically from one another as any coupling can adversely affect the size and direction of the ultrasound beam and the shape of the pulse transmitted to and detected from the tissue, thereby degrading the image.

Many ultrasound transducer arrays (linear, linear phased and 2-D arrays) currently used for medical imaging at conventional frequencies have a piezoelectric composite material as the active layer. A 1-3 piezoelectric composite, which has pillars of piezoelectric material surrounded by a passive material, takes advantage of the improved electromechanical coupling of tall, thin pillars of piezoelectric material and the lower net acoustic impedance compared to a bulk piezoelectric material. In addition, the composite material serves to reduce coupling to other array elements compared to a bulk piezoelectric material, although kerfs are usually cut between array elements to further suppress any coupling between array elements.

For high frequency transducer arrays, array elements may be defined by a pattern of array electrodes on the surface of the piezoelectric material rather than by a physical separation. Therefore the transducer array and the composite must be carefully designed to minimise any interaction between array elements or any unwanted vibration that would adversely affect an image.

A 1-3 piezoelectric composite is typically made from a bulk piece of piezoelectric material and cut (diced) in two directions with a thin dicing blade to make square piezoelectric pillars and the spaces filled with a polymer epoxy for stability. The pillar size and pillar pitch is small relative to the wavelength of interest for imaging with the transducer so that the composite acts as a homogeneous material. The conventional method of making kerfs in the piezoelectric material becomes more difficult with decreasing dimensions corresponding to increasing frequency, and is unlikely to be feasible for high frequency applications because of the small scale of the piezoelectric pillars.

The composite must also be ‘fine-scale’, such that the lateral dimensions of the composite structure are small relative to the thickness to prevent spurious (unwanted) modes that can occur in a regularly structured composite because of periodicity, symmetry and/or aspect ratio of the piezoelectric pillars.

If near enough in frequency, these structure-induced spurious modes, either between piezoelectric material, within the piezoelectric material or between array elements, which can interfere with the desired thickness-mode vibration of piezoelectric individual array elements and can prevent the elements from operating individually or acting essentially as a piston.

FIGS. 1 and 2 show an example of a prior art ultrasound transducer array 1. The transducer array 1 comprises a plurality of uniformly spaced piezoelectric pillars 3 made from a piezoelectric material and separated by straight channels. The piezoelectric pillars 3 are separated by a passive filler 5 made from epoxy. In addition, a further separation space is provided by a kerf 9 which is cut between array elements of the array in positions which correspond to the long edges (Y direction) of the array electrodes 13 which are mounted on the top of the piezoelectric 3 and epoxy 5 materials. It is clear from a visual inspection of FIGS. 1 and 2 that this ultrasound transducer array is constructed to have piezoelectric pillars arranged in a highly ordered manner i.e. the pillars are uniformly spaced and have a substantially square cross section as viewed from the XY plane in FIG. 1.

The above described structure may be modified by varying the position of the straight channels in order to change the distances between the piezoelectric pillars. The cross sectional area of the pillars may also be modified whilst retaining the general square or rectangular shape.

While the dice-and-fill techniques suffice to make the standard medical imaging transducers, operating up to 20 MHz, the fabrication of the composite becomes very difficult at higher frequencies because of the small lateral features required for efficient operation.

Control of spurious resonant modes and cross coupling between the array elements in a transducer array is a critical issue, particularly in high-frequency transducer arrays, operating at frequencies such as 20 MHz and above where such effects are greater because of the difficulty with conventional fabrication techniques in maintaining required lateral dimensions relative to the thickness. Therefore, spurious modes will occur at frequencies closer to the desired thickness mode, degrading array performance.

There is therefore a need for piezoelectric material-passive material composite substrates for, but not limited to, high-frequency ultrasound transducer arrays that suppress spurious modes within or between the segments of piezoelectric material and suppress electrical and mechanical coupling between array elements without physically separating array elements (e.g. with a kerf).

### SUMMARY OF THE INVENTION

In accordance with a first aspect of the present invention, there is provided a method for determining the shape of a piezoelectric material suitable for the formation of a piezoelectric composite, from which array elements in an ultrasound transducer array are formed, the method comprising the steps of:

calculating a spatial pattern of piezoelectric segments which form the piezoelectric composite material of the transducer array; wherein
the spatial pattern of the piezoelectric segments of the piezoelectric composite defines one or more non-linear, irregular channels which separate the piezoelectric segments thereby minimising interaction between the individual array elements and minimising spurious modes in the ultrasound transducer array.

Preferably, the method further comprises modelling one or more physical parameters associated with the ultrasound transducer array in order to determine the suitability of the composite based on its performance; wherein

Preferably, the method further comprises calculating the spatial locations at which one or more array electrodes are mountable on the surface of the piezoelectric composite such that the spatial locations designate the position of one or more array elements.

Preferably, the composite material beneath each electrode position comprises an array element.

Preferably, the step of generating a spatial pattern of piezoelectric segments comprises:

calculating a statistical spatial frequency distribution for the piezoelectric segments in the ultrasound transducer array based upon spatial frequency values and a correlation length;
creating a randomised statistical spatial frequency distribution by combining the statistical spatial frequency distribution with a random variable; and calculating the spatial pattern of the piezoelectric segments therefrom.

Preferably, the spatial frequency values are determined by composite size and the spatial resolution required in the spatial pattern.

Preferably, the correlation length is a measure of the distance over which the features of the piezoelectric composite material will change, or over which it is desired that these features change;

Preferably, the statistical spatial frequency distribution is based on a Gaussian distribution.

Preferably, the random variable is a function which provides a random number for each spatial frequency value.

Preferably, the step of calculating the spatial pattern comprises converting the randomised statistical spatial frequency distribution to a spatial domain distribution.

Preferably, the step of calculating the spatial pattern further comprises imposing a predetermined threshold value across the spatial domain distribution which determines the parts of the pattern which will be areas where piezoelectric material will be located and areas in which passive filler material will be located.

Preferably, the step of calculating the spatial location of the array electrodes comprises calculating array electrode pitch and array electrode width based on array dimensions and performance required for a specific application.

Preferably, the performance of an ultrasonic transducer array includes the electrical impedance response and/or electrical coupling between array elements and/or mechanical coupling between array elements and/or size of the ultrasound beam and/or direction of the ultrasound beam and/or the shape of the pulse transmitted to and detected from tissue.

Preferably, the step of modelling one or more physical parameters comprises finite element modelling.

Preferably, the physical parameters include electrical impedance response and/or wave propagation in the composite and/or the vibration modes of different shapes of piezoelectric segments and/or electrical and/or mechanical coupling between array elements and/or the desired operating frequency and/or piezoelectric composite physical dimensions and/or array electrode dimensions and/or the materials used.

Preferably, modelling of the piezoelectric composite is used to determine a range of parameters used in generating the spatial pattern of piezoelectric segments and the pattern of array elements that are suitable for a specific application.

Preferably, the parameters include correlation length, statistical spatial frequency distribution, random variable, array electrode width, array electrode pitch.

Preferably, the spatial pattern of piezoelectric segments is calculated in order to enhance the operation of one mode of vibration in the array elements.

Preferably, the thickness mode of vibration is enhanced.

Other vibration modes are pushed to frequencies away from the operating range or dispersed over a broad enough range to have minimal effect on the transducer array performance. By avoiding uniform or regular piezoelectric segment shapes and configurations, the net effect of spurious modes, either between piezoelectric segments, within the piezoelectric segments or between array elements, on the overall performance of the ultrasonic array is minimised.

Preferably, the shape of the piezoelectric material so determined is used to create a mould, template or other means for forming a piezoelectric transducer array.

In the present invention references to piezoelectric material includes both piezoelectric ceramic and piezoelectric single crystal materials.

Preferably, the piezoelectric material is amenable to various forming methods.

Preferably, the piezoelectric material is one which when formed comprises piezoelectric ceramic segments.

Preferably, the step of shaping a piezoelectric ceramic material comprises using net-shape or near net-shape fabrication.

Preferably, the net-shape or near net shape fabrication technique comprises a gel casting process, which uses a precursor piezoelectric ceramic made from a gel. Alternatively, the net-shape or near net shape fabrication technique comprises a viscous polymer processing (VPP) process, wherein

the precursor piezoelectric ceramic is a paste.

Due to gel and paste being amenable to various forming methods, the piezoelectric ceramic can be easily positioned anywhere and in any geometry in a 2-dimensional plate using moulds. Hence the position, size and geometry of the piezoelectric ceramic and the spaces between the moulded piezoelectric ceramic can be set so as to eliminate spurious modes.

Optionally, the step of shaping the piezoelectric ceramic material comprises etching.

Optionally, the step of shaping the piezoelectric ceramic material comprises ink jet printing.

Alternatively, the material is one which when formed comprises piezoelectric single crystal segments.

Preferably, the step of shaping the piezoelectric single crystal material comprises etching.

Due to piezoelectric ceramics and single crystals being amenable to etching methods of shaping, the position of the piezoelectric material can be set in any geometry in a 2-dimensional plate using a template or mask. Hence the position, size and geometry of the piezoelectric material and the spaces between the etched piezoelectric material can be set so as to eliminate spurious modes.

Preferably, one or more of the piezoelectric segments that form an array element has protrusions outwards towards other array elements in order to disrupt the propagation of waves laterally across the transducer array.

In accordance with a second aspect of the invention there is provided a method of making an ultrasonic transducer array having a plurality of individual array elements made from a piezoelectric composite which is made from a plurality of individual piezoelectric segments, the method comprising the steps of:

shaping a material which forms the piezoelectric segments such that the material conforms to a spatial pattern of the piezoelectric material within the piezoelectric composite of the ultrasound transducer array;
adding a passive filler between the piezoelectric segments; and
providing one or more electrodes for driving the array elements formed from the piezoelectric segments;
such that the spatial pattern of the piezoelectric segments of the piezoelectric composite defines one or more non-linear, irregular channels which separate the piezoelectric segments thereby minimising interaction between the individual array elements and minimising spurious modes in the ultrasound transducer array.

Preferably, the method further comprises modelling one or more physical parameters associated with the ultrasound transducer array in order to determine the suitability of the composite based on its performance.

Preferably, the step of providing electrodes comprises calculating the spatial locations at which one or more array electrodes are mountable on the surface of the piezoelectric composite such that the spatial locations designate the position of one or more array elements.

Preferably, the volume of the composite material beneath each electrode position comprises an array element.

Preferably, the spatial pattern of piezoelectric segments is calculated in order to enhance the operation of one mode of vibration in the array elements.

Preferably, the thickness mode of vibration is enhanced.

Other vibration modes are pushed to frequencies away from the operating range or dispersed over a broad enough range to have minimal effect on the transducer array performance. By avoiding uniform or regular piezoelectric segment shapes and configurations, the net effect of spurious modes, either between piezoelectric segments, within the piezoelectric segments or between array elements, on the overall performance of the ultrasonic array is minimised.

Preferably, the spatial pattern of piezoelectric segments is calculated by:

calculating a statistical spatial frequency distribution for the piezoelectric segments in the ultrasound transducer array based upon spatial frequency values and a correlation length;
creating a randomised statistical spatial frequency distribution by combining the statistical spatial frequency distribution with a random variable; and
calculating the spatial pattern of the piezoelectric segments therefrom; wherein
the spatial frequency values are determined by composite size and the spatial resolution required in the spatial pattern, and
the correlation length is a measure of the distance over which the features of the piezoelectric composite material will change, or over which it is desired that these features change;

Preferably, the statistical spatial frequency distribution is based on a Gaussian distribution.

Preferably, the random variable is a function which provides a random number for each spatial frequency value.

Preferably, the spatial pattern is calculated by converting the randomised statistical spatial frequency distribution to a spatial domain distribution.

Preferably, the spatial pattern is calculated by imposing a predetermined threshold value across the spatial domain distribution which determines the parts of the pattern which will be areas where piezoelectric material will be located and areas in which passive filler material will be located.

In the present invention references to piezoelectric material includes both piezoelectric ceramic and piezoelectric single crystal materials.

Preferably, the piezoelectric material is amenable to various forming methods.

Preferably, the piezoelectric material is one which when formed comprises piezoelectric ceramic segments.

Preferably, the step of shaping a piezoelectric ceramic material comprises using net-shape or near net-shape fabrication.

Preferably, the net-shape or near net shape fabrication technique comprises a gel casting process, wherein a precursor piezoelectric ceramic is a gel.

Alternatively, the net-shape or near net shape fabrication technique comprises a viscous polymer processing (VPP) process, wherein

the precursor piezoelectric ceramic is a paste.

Due to gel and paste being amenable to various forming methods, the piezoelectric ceramic can be easily positioned anywhere and in any geometry in a 2-dimensional plate using moulds. Hence the position, size and geometry of the piezoelectric ceramic and the spaces between the moulded piezoelectric ceramic can be set so as to eliminate spurious modes.

Optionally, the step of shaping the piezoelectric ceramic material comprises etching.

Optionally, the step of shaping the piezoelectric ceramic material comprises ink jet printing.

Alternatively, the material is one which when formed comprises piezoelectric single crystal segments.

Preferably, the step of shaping the piezoelectric single crystal material comprises etching.

Due to piezoelectric ceramics and single crystals being amenable to etching methods of shaping, the position of the piezoelectric material can be set in any geometry in a 2-dimensional plate using a template or mask. Hence the position, size and geometry of the piezoelectric material and the spaces between the etched piezoelectric material can be set so as to eliminate spurious modes.

Preferably, one or more of the piezoelectric segments that form an array element has protrusions outwards into other array elements in order to disrupt the propagation of waves laterally across the transducer array.

In accordance with a third aspect of the invention there is provided an ultrasonic transducer array comprising: a plurality of individual array elements made from a piezoelectric composite which is made from a plurality of individual piezoelectric segments;

a passive filler between the piezoelectric segments; and
one or more electrodes for driving the array elements formed from the piezoelectric segments; wherein
the spatial pattern of the piezoelectric segments of the piezoelectric composite defines one or more non-linear, irregular channels which separate the piezoelectric segments thereby minimising interaction between the individual array elements and minimising spurious modes in the ultrasound transducer array.

Preferably, one or more array electrodes are mountable on the surface of the piezoelectric composite such that the spatial locations designate the position of one or more array elements.

Preferably, the volume of the composite material beneath each electrode comprises an array element.

Preferably, the spatial pattern of piezoelectric segments is calculated in order to enhance the operation of one mode of vibration in the array elements.

Preferably, the thickness mode of vibration is enhanced.

Other vibration modes are pushed to frequencies away from the operating range or dispersed over a broad enough range to have minimal effect on the transducer array performance. By avoiding uniform or regular piezoelectric segment shapes and configurations, the net effect of spurious modes, either between piezoelectric segments, within the piezoelectric segments or between array elements, on the overall performance of the ultrasonic array is minimised.

Preferably, the spatial pattern of piezoelectric segments is calculated by:

calculating a statistical spatial frequency distribution for the piezoelectric segments in the ultrasound transducer array based upon spatial frequency values and a correlation length;
creating a randomised statistical spatial frequency distribution by combining the statistical spatial frequency distribution with a random variable; and
calculating the spatial pattern of the piezoelectric segments therefrom; wherein
the spatial frequency values are determined by composite size and the spatial resolution required in the spatial pattern, and
the correlation length is a measure of the distance over which the features of the piezoelectric composite material will change, or over which it is desired that these features change;

Preferably, the statistical spatial frequency distribution is based on a Gaussian distribution.

Preferably, the random variable is a function which provides a random number for each spatial frequency value.

Preferably, the spatial pattern is calculated by converting the randomised statistical spatial frequency distribution to a spatial domain distribution.

Preferably, the spatial pattern is calculated by imposing a predetermined threshold value across the spatial domain distribution which determines the parts of the pattern which will be areas where piezoelectric material will be located and areas in which passive filler material will be located.

In the present invention references to piezoelectric material includes both piezoelectric ceramic and piezoelectric single crystal materials.

Preferably, the piezoelectric material is amenable to various forming methods.

Preferably, the piezoelectric material is one which when formed comprises piezoelectric ceramic segments.

Preferably, the piezoelectric ceramic material is shaped using net-shape or near net-shape fabrication.

Preferably, the net-shape or near net shape fabrication technique comprises a gel casting process, wherein the precursor piezoelectric ceramic is a gel.

Alternatively, the net-shape or near net shape fabrication technique comprises a viscous polymer processing (VPP) process, wherein the precursor piezoelectric ceramic is a paste.

Due to gel and paste being amenable to various forming methods, the piezoelectric ceramic can be easily positioned anywhere and in any geometry in a 2-dimensional plate using moulds. Hence the position, size and geometry of the piezoelectric ceramic and the spaces between the moulded piezoelectric ceramic can be set so as to eliminate spurious modes.

Optionally, the piezoelectric ceramic material is etched.

Optionally, the step of shaping the piezoelectric ceramic material comprises ink jet printing.

Alternatively, the material is one which when formed comprises piezoelectric single crystal segments.

Preferably, the piezoelectric single crystal material is etched.

Due to piezoelectric ceramics and single crystals amenable to etching methods of shaping, the position of the piezoelectric material can be set in any geometry in a 2-dimensional plate using a template or mask. Hence the position, size and geometry of the piezoelectric material and the spaces between the etched piezoelectric material can be set so as to eliminate spurious modes.

Preferably, one or more of the piezoelectric segments that form an array element protrudes outwards into other array elements in order to disrupt the propagation of waves laterally across the transducer array.

### BRIEF DESCRIPTION OF THE DRAWINGS

The present invention will now be described by way of example only with reference to the accompanying drawings in which:

FIG. 1 is a perspective view of part of a prior art ultrasound transducer array;

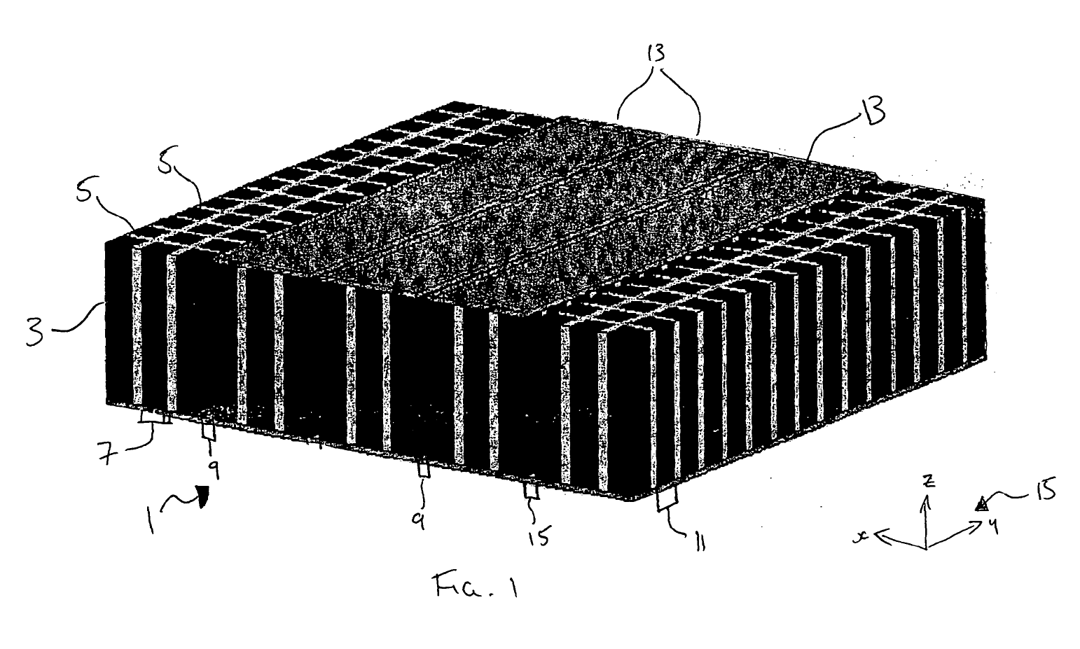

FIG. 2 is a side view of part of the prior art transducer array of FIG. 1;

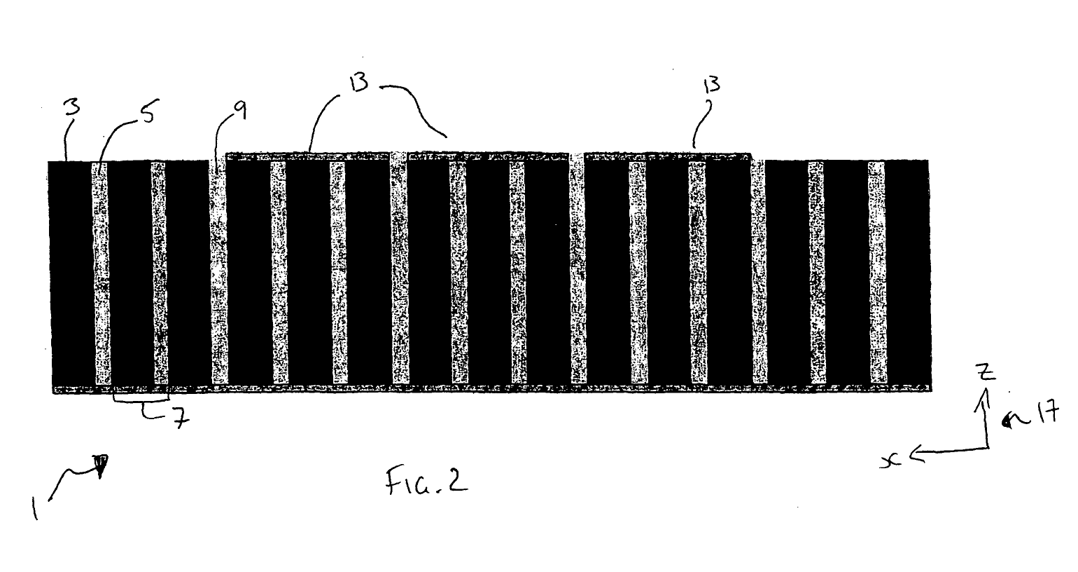

FIG. 3 is a perspective view of part of an example of an ultrasound transducer array in accordance with the present invention;

FIG. 4 is a side view of part of the example of an ultrasound transducer array shown in FIG. 3;

FIG. 5 is a plan view of part of the example of an ultrasound transducer array shown in FIG. 3;

FIGS. 6a and 6b are plan views of part of two examples of a prior art ultrasound transducer array;

FIG. 7 is a plan view of part of another embodiment of an ultrasound array in accordance with the present invention;

FIGS. 8a and 8b are graphs of normalised electrical impedance amplitude against frequency and electrical impedance phase against frequency for the prior art ultrasound transducer of FIG. 6;

FIGS. 9a and 9b are graphs of normalised electrical impedance amplitude against frequency and electrical impedance phase against frequency for the ultrasound transducer of FIG. 7; and

FIG. 10 is a flow diagram which describes the steps in one example of calculating the shape of the piezoelectric material in the ultrasound transducer array.

### DETAILED DESCRIPTION OF THE DRAWINGS

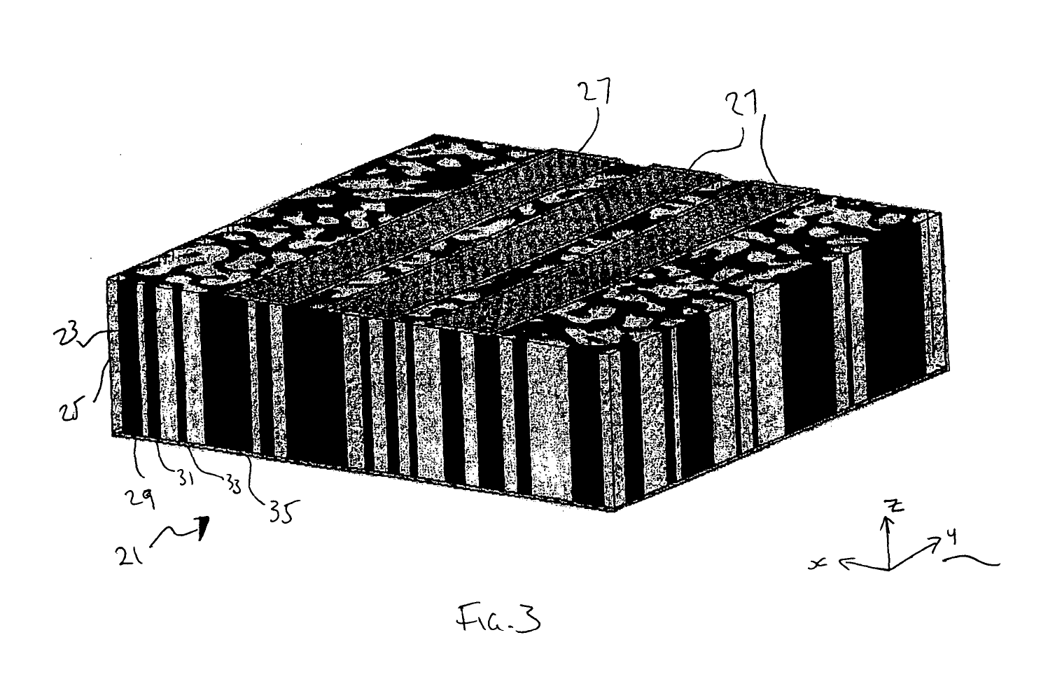

FIGS. 3 to 5 show an embodiment of an ultrasound transducer array in accordance with the present invention.

FIG. 3 is a perspective view of an ultrasound transducer array 21 comprising piezoelectric material segments 23 combined with a passive epoxy filler 25. Electrodes 27 are provided on top of the array 21 to drive the piezoelectric segments 23. The positions of the electrodes 27 designate the position of the array elements, such that the volume of the material beneath (Z-direction) each array electrode comprises an individual array element.

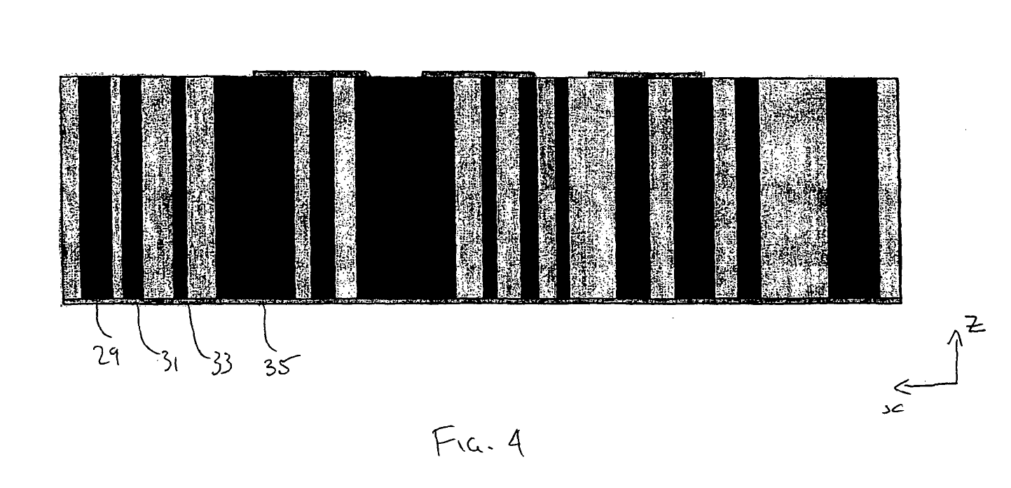

As is apparent from FIGS. 3 and 4, the distribution of piezoelectric material 23 across the transducer array 21 is non uniform. Segments 29, 31, 33 and 35 are all of different widths and the distances between the segments are non-identical.

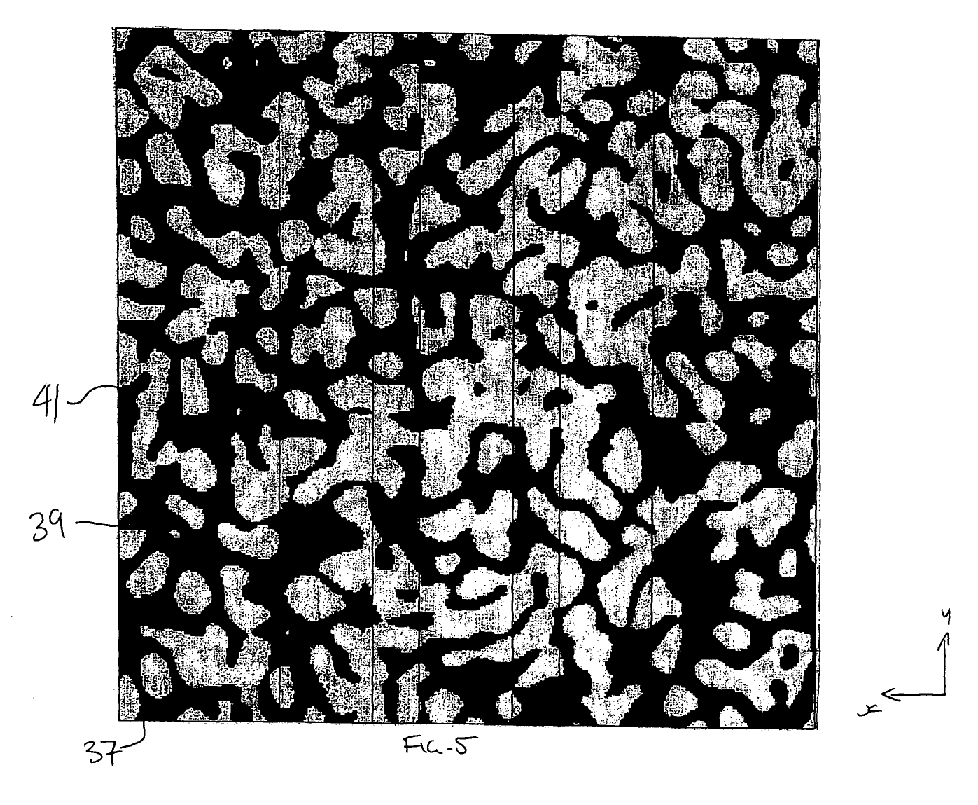

FIGS. 3 and 5 show the manner in which the piezoelectric material segments have been arranged across the surface in the YX plane of the figures. The pattern shown is clearly non-uniform and lacks an ordered structure. This can be seen by comparing the shapes of the areas identified by reference numerals 37, 39 and 41.

The spatial distribution of piezoelectric material shown in FIGS. 3 to 5 is one pattern which has been created based on correlation length of piezoelectric material segment connectivity required for operating at a predetermined operating frequency.

Another embodiment of the present invention is described below. In this example, a comparison is made between the frequency response of a regular (prior art) array and one made in accordance with the present invention.

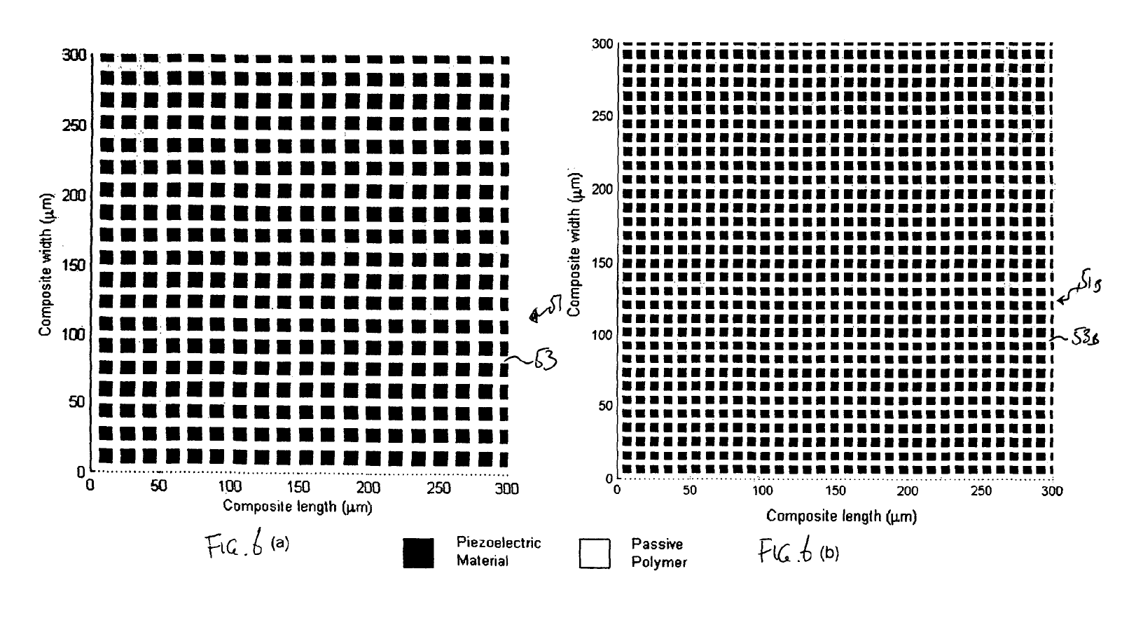

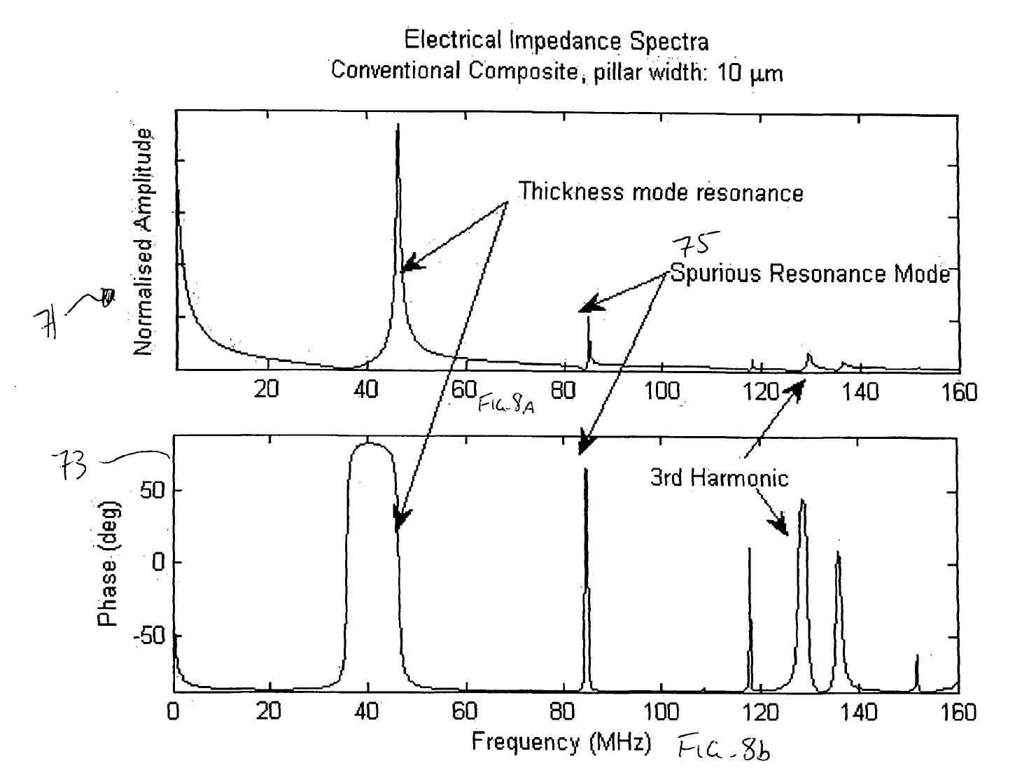

FIGS. 6a and 6b 6 show two examples of composites with different pillar sizes. Both show a conventional composite design 51, 51b that is finer-scale than is achievable with conventional dicing fabrication processes. In FIG. 6a, the composite has a regular geometry 53 and 10 μm pillars and 40% volume fraction piezoelectric material. This pattern has been modelled as a 40 μm thick, 300 μm square device with a common piezoelectric ceramic and common passive epoxy filler. In FIG. 6b the pillar size is 6 μm. The corresponding graphs shown in FIGS. 8a and 8b of normalised electrical impedance amplitude against frequency 71 and electrical impedance phase against frequency 73 shows spurious modes 75 within the frequency range of interest.

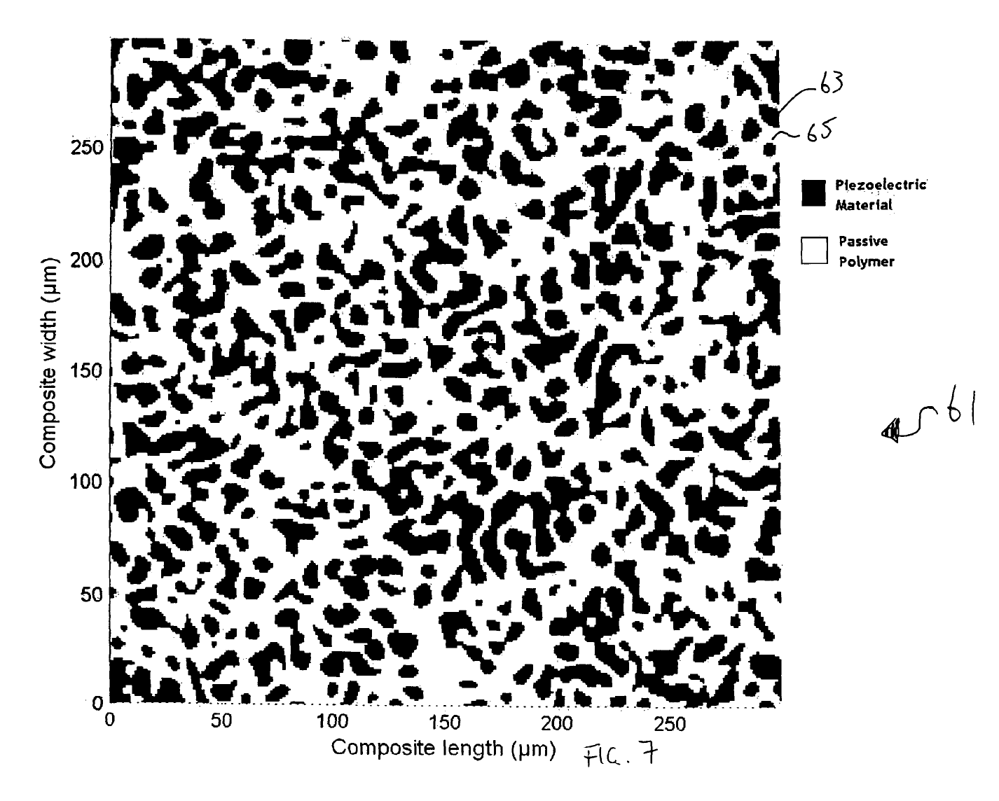

The composite of FIG. 6a has the same volume fraction of piezoelectric material as the randomised composite of FIG. 7, but a spurious lateral mode, due to the periodicity of the pillar positions, occurs at about 85 MHz. In order for a composite to operate with a thickness mode near 50 MHz, spurious modes below at least 100 MHz should be suppressed to ensure uni-modal response. Preferably, there should be no spurious modes below the third harmonic, as is the case for the randomised composite. Therefore, the pitch of the composite, and consequently the pillar width and kerf width must be reduced.

A regular composite with 40% volume fraction piezoelectric material and pillars as small as 6 μm, as shown in FIG. 6b is required to push the frequency of the spurious lateral mode above the third harmonic.

This pillar size is significantly lower than that achieved currently. Regular composites having round pillars with 20 μm diameter have been fabricated with moulding processes. However, decreasing the size and pitch of regular, tall, thin pillars significantly further with a ceramic moulding process is likely to be very challenging.

The design of a composite with a randomised pattern of piezoelectric material is shown in FIG. 7. The pattern 61, shown in FIG. 7 has a correlation length, of 10 μm, indicating the nominal dimensions of the segments of piezoelectric material within the composite. The volume fraction piezoelectric material within a composite with this pattern is 40%, and standard piezoelectric ceramic 63 and polymer filler 65 materials have been used in the model. This pattern has been modelled as a 40 μm thick, 300 μm square device.

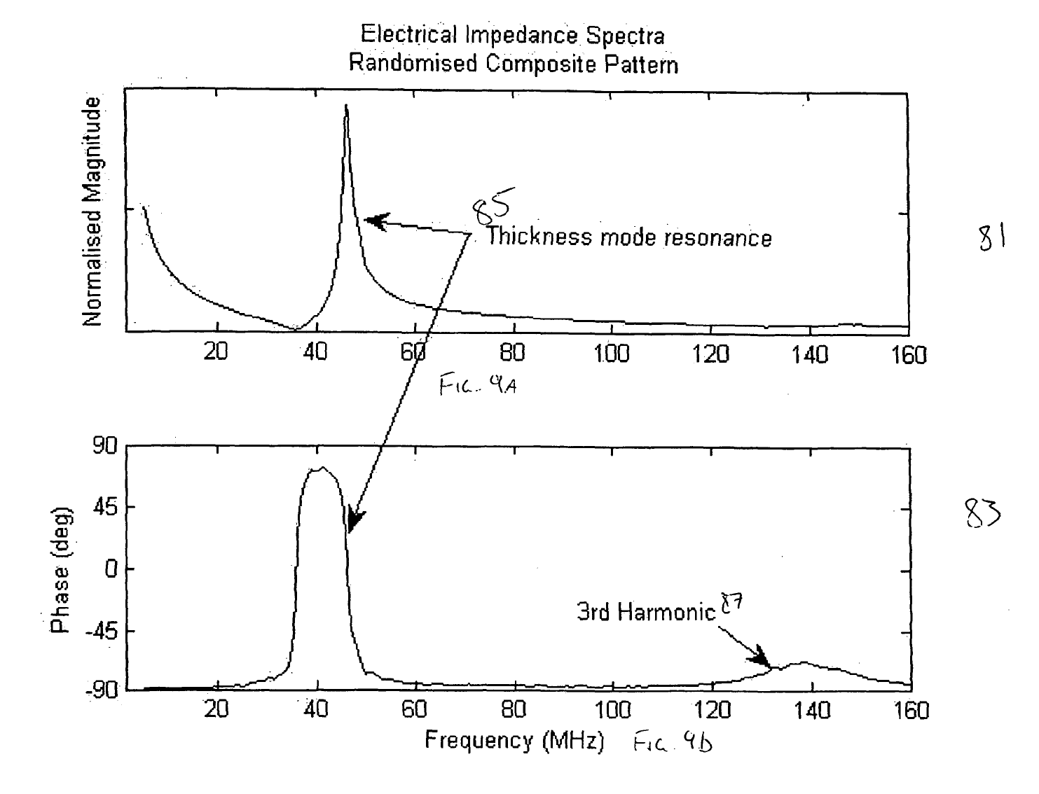

FIGS. 9a and 9b are graphs of normalised electrical impedance amplitude against frequency 81 and electrical impedance phase against frequency 83 for the ultrasound transducer of FIG. 7. The electrical impedance magnitude and phase indicate a single resonance mode 85 at the expected frequency of 46 MHz. There are no spurious modes even up to the frequency of the third harmonic. In addition, the electromechanical coupling factor, k_{T}, a standard measure of the efficiency of a composite, is 0.68, which is equal to the theoretical coupling coefficient for a composite with these materials and volume fraction piezoelectric ceramic.

Irregular shapes of ceramic can be moulded with minimum lateral dimensions below 6 μm.

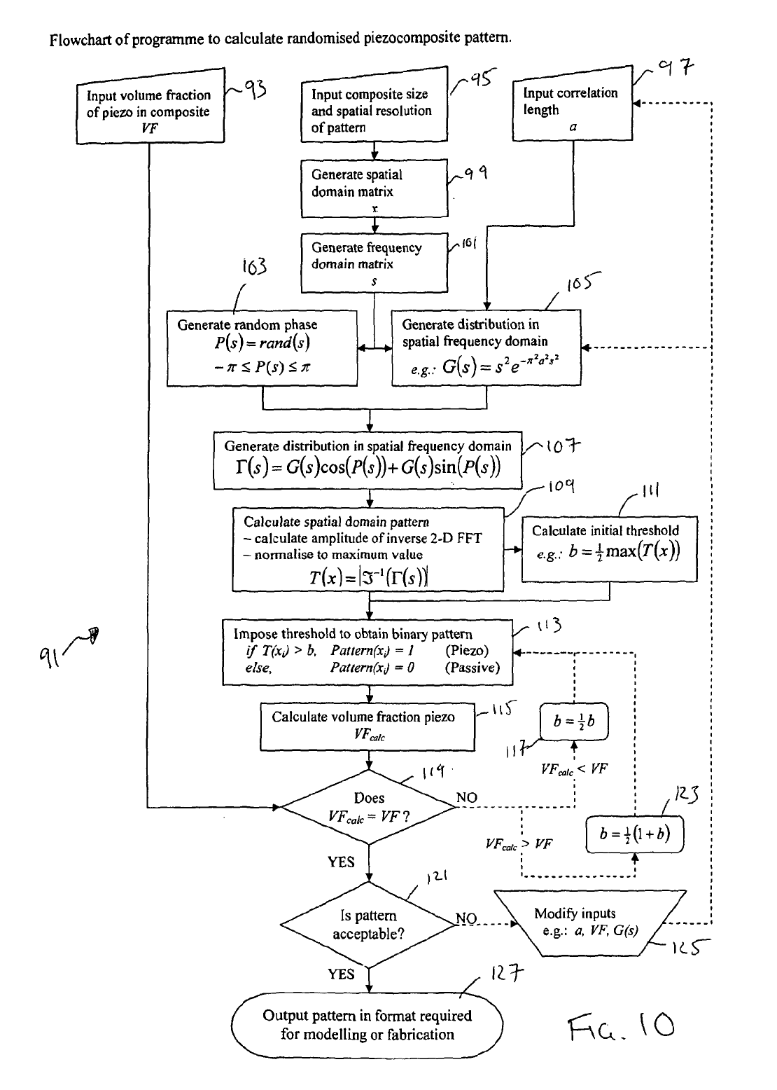

FIG. 10 is a flowchart 91 which shows one example of the method by which the spatial distribution of piezoelectric segments is calculated in order to create a transducer array in accordance with the invention.

In this example the flowchart shows four examples of physical parameters that are used in order to create a pattern of spatial distribution. These parameters are the piezoelectric material volume fraction, composite size, spatial resolution of pattern and correlation length. The volume fraction is the percentage of piezoelectric material in the piezoelectric composite material. Typically the volume fraction will be between twenty and eighty percent of the overall material volume. The value of composite size is simply the overall dimensions of the composite material. Typically this can be 2 mm×2 mm, 2 mm×4 mm or 2 mm×5 mm. The spatial resolution, or digitisation, of the pattern is the minimum dimension to be reproduced in the mould, template or mask and therefore in the composite; the smaller the features needed, the higher the resolution required. The correlation length is a statistically created measure of the degree of “sameness” at any point on the notional surface of the composite material. The correlation length is a measure of the distance over which the features of the piezoelectric composite material will change, or over which it is desired that these features change.

In the flowchart, the composite size values, and spatial resolution values are input 95 and a spatial domain matrix 99 is generated from these values. The spatial domain matrix or grid 99 provides the positions for localising the pattern of material within the piezoelectric composite. The spatial domain matrix 99 is used to create a spatial frequency domain matrix 101 in which the frequency increment is the inverse of the spatial position increment. Thereafter, the spatial frequency domain matrix 101 is combined with the input correlation length 97 to generate a Gaussian distribution 105 which is combined with a random function over the spatial frequency domain matrix 103 in order to generate a random distribution in the spatial frequency domain 107.

Thereafter an inverse Fourier transform is applied in order to calculate a spatial domain distribution 109. In this example of the present invention, the spatial domain distribution is a continuous function. Therefore it is necessary to convert it into a binary pattern by applying a threshold value to the pattern. The binary values 1 and 0 correspond to areas of piezoelectric material and areas of passive filler material respectively. The binary pattern can be represented visually by a black and white pattern as shown in FIG. 7.

The initial stage of this process is to calculate a threshold value or to simply set this value to a desired level. This step is shown in box 111. Once this has been done, areas of the spatial distribution pattern derived in box 109 which are above the threshold will be defined as representing piezoelectric material and areas which are below the threshold will be defined as representing passive filler material 113.

The volume fraction of the piezoelectric material in the calculated spatial domain pattern is found and compared with an input volume fraction of piezoelectric material 119. If these are unequal, a new threshold value is imposed 113 and the calculation is re-done. Once the calculated volume fraction and the input volume fraction are equal 119, the acceptability of the pattern is assessed and if it is deemed acceptable 127, an output is created which allows a transducer array to be created. If unacceptable, modifications 125 are incorporated in the design.

The pattern is deemed acceptable or unacceptable by inspecting for fabrication feasibility and by modelling. Finite element modelling of sections of a composite is used in order to determine the performance of a given composite pattern and confirm its suitability for an application.

The output of the pattern calculation process may be used to create a mould or other type of template for creating the piezoelectric composite and the transducer array.

The shapes of the moulds, templates, or other means used to create the structures can be inferred from the final shape of the device.

It will be appreciated that the above example of the present invention provides one way of distributing the piezoelectric segments in order to create non-linear irregular channels of passive material in the composite material which forms the substrate for an ultrasound transducer array. The purpose of the novel techniques used in the above example is to create a pattern which when applied to the placement of piezoelectric segments and channels will reduce or remove unwanted ultrasound frequencies from the operating range of the device.

Creation of an ultrasound transducer array in accordance with the present invention has been achieved using a net-shape ceramic fabrication technique based on either viscous polymer processing (VPP) or gelcasting processes to produce composites with complex piezoelectric ceramic segment geometries and ultrafine (<10 microns) lateral features leading to greater design flexibility. Due to the highly plastic nature of the ceramic paste or the fluid nature of the gel (which are thus amenable to various forming methods), the ceramic can be positioned anywhere and in any geometry in a 2-dimensional plate using moulds. Hence the position, size and geometry of the ceramic and the spaces between the moulded ceramic can be set so as to eliminate spurious modes.

In one example of the gel casting technique, a piezoelectric ceramic powder, organic monomers and a solvent dispersant are formed into a slurry which is combined with an initiator. The mixture then undergoes centrifugal casting, gelation, demoulding and is finally sintered.

Calculating and adopting a complex, irregular or non-uniform spatial distribution minimises undesirable vibration modes within the transducer array. In this example, the only coherent mode operating in the composite plate is the thickness mode, with other modes pushed to frequencies away from the operating range or dispersed over a broad enough range to have minimal effect on the transducer performance.

The design of the composite (piezoelectric material and passive filler) for specific applications will change depending upon for example, the desired operating frequency, its physical dimensions and the materials used. The composite for each type of array is expected to be different due to changing size and performance requirements.

Finite element modelling of sections of a composite is used in order to check the dimensions and positions required in the composite. This includes a study of wave propagation in the composite and the vibration modes of different piezoelectric segments in the composite, and a calculation of the electrical impedance spectrum.

Structures with random, pseudo-random or distribution of piezoelectric segment size and pitch relax the restrictions imposed on a composite to be ‘fine-scale’, such that lateral dimensions of the pattern are much smaller than its thickness, whilst maintaining the performance and giving an effectively homogenous composite plate. This is of particular benefit for high-frequency transducers where the critical dimension is reduced.

In addition, the position of the piezoelectric material can be set to define array elements along with the pattern of electrodes on the surface of the composite. Piezoelectric segments can protrude from volume designated as one element in order to disrupt propagating waves generated at the edge of the array, and with dimensions to minimise coupling between array elements through piezoelectric segments.

The protrusion of piezoelectric segments from the volume designated as one array element into the volume designated as other elements will serve to stiffen the composite, making any lateral modes operate at higher frequencies. The protrusions will also serve to scatter/disturb waves propagating in the composite when they arrive at the edge of an element, minimising the piezoelectric stiffening effect of non-excited array electrodes on a set of piezoelectric pillars which can promote coherent waves along the length of an array. The piezoelectric stiffening effect in regular and aligned array elements, each of which has a common electrode connecting a region of piezoelectric segments, can cause somewhat incoherent wavefronts to align with the length of array elements and become coherent, potentially producing spurious inter-element modes

An additional possibility is to use sparse, or aperiodic array patterns to suppress spurious modes related to array periodicity.

The present invention provides:
non-identical shapes and/or relative positions of at least some of the piezoelectric segments of the composite to suppress or distribute spurious modes within piezoelectric segments;
non-identical shapes and/or relative positions of at least some of the piezoelectric segments in the composite to suppress or distribute spurious modes between piezoelectric segments in the composite;
Array element shape determined by form of piezoelectric segments that are in contact with the element electrode;
Edges of elements formed in such a way so as to scatter/disturb waves that propagate in the composite plate away from an excited element; and
Composite and array pattern designed together to minimise inter-element interaction by minimising electrical cross-talk through piezoelectric material between two electrodes, while maintaining a distribution of sizes and shapes to suppress spurious vibration modes.

The present invention can be used for high frequency-high resolution medical ultrasound imaging. In this context the apparatus of the present invention may be used in equipment for dermatology, ophthalmology, dentistry and intravascular imaging, as well as small animal imaging for pre-clinical purposes.

Improvements and modifications may be incorporated herein without deviating from the scope of the invention.

1. A method for determining the shape of a piezoelectric material suitable for the formation of a piezoelectric composite, from which array elements in an ultrasound transducer array are formed, the method comprising the steps of:
calculating a spatial pattern of piezoelectric segments which form the piezoelectric composite material of the transducer array wherein the spatial pattern of the piezoelectric segments of the piezoelectric composite defines one or more non-linear, irregular channels which separate the piezoelectric segments thereby minimising interaction between the individual array elements and minimising spurious modes in the ultrasound transducer array.

2. The method as claimed in claim 1 wherein one or more physical parameters associated with the ultrasound transducer array are modelled in order to determine the suitability of the composite based on its performance.

3. The method as claimed in claim 1 which further comprises calculating the spatial locations at which one or more array electrodes are mountable on the surface of the piezoelectric composite such that the spatial locations designate the position of one or more array elements.

4. The method as claimed in claim 3 wherein, the composite material beneath each electrode position comprises an array element.

5. The method as claimed in claim 1 wherein, the step of generating a spatial pattern of piezoelectric segments comprises:
calculating a statistical spatial frequency distribution for the piezoelectric segments in the ultrasound transducer array based upon spatial frequency values and a correlation length; creating a randomised statistical spatial frequency distribution by combining the statistical spatial frequency distribution with a random variable; and calculating the spatial pattern of the piezoelectric segments therefrom.

6. The method as claimed in claim 5 wherein, the spatial frequency values are determined by composite size and the spatial resolution required in the spatial pattern.

7. The method as claimed in claim 5 wherein, the correlation length is a measure of the distance over which the features of the piezoelectric composite material will change, or over which it is desired that these features change.

8. The method as claimed in claim 5 wherein, the statistical spatial frequency distribution is based on a Gaussian distribution.

9. The method as claimed in claim 5 wherein, the random variable is a function which provides a random number for each spatial frequency value.

10. The method as claimed in claim 1 wherein, the step of calculating the spatial pattern comprises one or more of the following:
converting the randomised statistical spatial frequency distribution to a spatial domain distribution; and
imposing a predetermined threshold value across the spatial domain distribution which determines the parts of the pattern which will be areas where piezoelectric material will be located and areas in which passive filler material will be located.

11. (canceled)

12. The method as claimed in claim 3 wherein, the step of calculating the spatial location of the array electrodes comprises calculating array electrode pitch and array electrode width based on array dimensions and performance required for a specific application.

13. The method as claimed in claim 2 wherein, modelling of the piezoelectric composite is used to determine a range of parameters used in generating the spatial pattern of piezoelectric segments and the pattern of array elements that are suitable for a specific application.

14. The method as claimed in claim 13 wherein, the parameters include correlation length and/or statistical spatial frequency distribution and/or a random variable and/or array electrode width and/or array electrode pitch.

15. The method as claimed claim 1 wherein, the spatial pattern of piezoelectric segments is calculated in order to enhance the operation of one mode of vibration in the array elements.

16. The method as claimed in claim 15 wherein, the thickness mode of vibration is enhanced.

17. The method as claimed in claim 1 wherein, the shape of the piezoelectric material so determined is used to create a mould, template or other means for forming a piezoelectric transducer array.

18. (canceled)

19. The method as claimed in claim 1 wherein, the piezoelectric material is one which when formed comprises one or more of the following:
piezoelectric ceramic segments; and
piezoelectric crystal segments.

20. The method as claimed in claim 19 wherein, the shape of the piezoelectric material is created using one or more of the following techniques:
net-shape or near net-shape fabrication;
etching; and
ink jet printing.

21. The method as claimed in claim 20 wherein, the net-shape or near net shape fabrication technique comprises one or more of the following:
a gel casting process, which uses a precursor piezoelectric ceramic made from a gel; and
a viscous polymer processing (VPP) process, wherein the precursor piezoelectric ceramic is a paste.

22.-26. (canceled)

27. The method as claimed in claim 1 wherein, one or more of the piezoelectric segments that form an array element has protrusions outwards towards other array elements in order to disrupt the propagation of waves laterally across the transducer array.

28. A method of making an ultrasonic transducer array having a plurality of individual array elements made from a piezoelectric composite which is made from a plurality of individual piezoelectric segments, the method comprising the steps of:
shaping a material which forms the piezoelectric segments such that the material conforms to a spatial pattern of the piezoelectric material within the piezoelectric composite of the ultrasound transducer array;
adding a passive filler between the piezoelectric segments; and
providing one or more electrodes for driving the array elements formed from the piezoelectric segments; such that the spatial pattern of the piezoelectric segments of the piezoelectric composite defines one or more non-linear, irregular channels which separate the piezoelectric segments thereby minimising interaction between the individual array elements and minimising spurious modes in the ultrasound transducer array.

29. The method as claimed in claim 28 wherein one or more physical parameters associated with the ultrasound transducer array are modelled in order to determine the suitability of the composite based on its performance.

30. The method as claimed in claim 28 wherein, the step of providing electrodes comprises calculating the spatial locations at which one or more array electrodes are mountable on the surface of the piezoelectric composite such that the spatial locations designate the position of one or more array elements.

31. The method as claimed in claim 29 wherein, the composite material beneath each electrode position comprises an array element.

32. The method as claimed claim 29 wherein, the spatial pattern of piezoelectric segments is calculated in order to enhance the operation of one mode of vibration in the array elements.

33. The method as claimed in claim 32 wherein, the thickness mode of vibration is enhanced.

34. The method as claimed in claim 28 wherein, the spatial pattern of piezoelectric segments is calculated by:
calculating a statistical spatial frequency distribution for the piezoelectric segments in the ultrasound transducer array based upon spatial frequency values and a correlation length;
creating a randomised statistical spatial frequency distribution by combining the statistical spatial frequency distribution with a random variable; and
calculating the spatial pattern of the piezoelectric segments therefrom;
wherein the spatial frequency values are determined by composite size and the spatial resolution required in the spatial pattern, and the correlation length is a measure of the distance over which the features of the piezoelectric composite material will change, or over which it is desired that these features change.

35. The method as claimed in claim 34 wherein, the statistical spatial frequency distribution based on a Gaussian distribution.

36. The method as claimed in claim 34 wherein, the random variable is a function which provides a random number for each spatial frequency value.

37. The method as claimed in claim 34 wherein, the spatial pattern is calculated by converting the randomized statistical spatial frequency distribution to a spatial domain distribution.

38. The method as claimed, in claim 37 wherein, the spatial pattern is calculated by imposing a predetermined threshold value across the spatial domain distribution which determines the parts of the pattern which will be areas where piezoelectric material will be located and areas in which passive filler material will be located.

39. (canceled)

40. The method as claimed in claim 28 wherein, the piezoelectric material is one which when formed comprises one or more of the following:
piezoelectric ceramic segments; and
piezoelectric single crystal segments.

41. The method as claimed in claim 39 wherein, the shape of the piezoelectric material is created using one or more of the following techniques:
net-shape or near net-shape fabrication;
etching; and
ink jet printing.

42. The method as claimed in claim 41 wherein, the net-shape or near net shape fabrication technique comprises one or more of the following:
a gel casting, process, which uses a precursor piezoelectric ceramic made from a gel; and
a viscous polymer processing (VPP) process, wherein the precursor piezoelectric ceramic is a paste.

43.-47. (canceled)

48. The method as claimed claim 28 wherein, one or more of the piezoelectric segments that form an array element has protrusions outwards towards other array elements in order to disrupt the propagation of waves laterally across the transducer array.

49. An ultrasonic transducer array comprising:
a plurality of individual array elements made from a piezoelectric composite which is made from a plurality of individual piezoelectric segments;
a passive filler between the piezoelectric segments; and
one or more electrodes for driving the array elements formed from the piezoelectric segments; wherein the spatial pattern of the piezoelectric segments of the piezoelectric composite defines one or more non-linear, irregular channels which separate the piezoelectric segments thereby minimising interaction between the individual array elements and minimising spurious modes in the ultrasound transducer array.

50. The ultrasonic transducer array as claimed in claim 49 wherein, one or more array electrodes are mountable on the surface of the piezoelectric composite such that the spatial locations designate the position of one or more array elements.

51. The ultrasonic transducer array as claimed in claim 49 wherein, the composite material beneath each electrode comprises an individual array element.

52. The ultrasonic transducer array as claimed in claim 49 wherein, the spatial pattern of piezoelectric segments is calculated in order to enhance the operation of one mode of vibration in the array elements.

53. The ultrasonic transducer array as claimed in claim 52 wherein, the thickness mode of vibration is enhanced.

54. The ultrasonic transducer array, as claimed in claim 49 wherein the spatial pattern of piezoelectric segments is calculated by
calculating a statistical spatial frequency distribution for the piezoelectric segments in the ultrasound transducer array based upon spatial frequency values and a correlation length;
creating a randomised statistical spatial frequency distribution by combining the statistical spatial frequency distribution with a random variable; and
calculating, the spatial pattern of the piezoelectric segments therefrom; wherein the spatial frequency values are determined by composite size and the spatial resolution required in the spatial pattern, and the correlation length is a measure of the distance over which the features of the piezoelectric composite material will change, or over which it is desired that these features change.

55. The ultrasonic transducer array, as claimed in claim 54 wherein, the statistical spatial frequency distribution is based on a Gaussian distribution.

56. The ultrasonic transducer as claimed in claim 54 wherein, the random variable is a function which provides a random number for each spatial frequency value.

57. The ultrasonic transducer array as claimed in claim 54 wherein, the spatial pattern is calculated by converting the randomised statistical spatial frequency distribution to a spatial domain distribution.

58. The ultrasonic transducer array as claimed in claim 49 wherein, the piezoelectric material is one which when formed comprises one or more of the following:
piezoelectric ceramic segments; and
piezoelectric single crystal segments.

59. The ultrasonic transducer array method as claimed in claim 57 wherein, the shape of the piezoelectric material is created using one or more of the following techniques:
net-shape or near net-shape fabrication;
etching; and
ink jet printing.

60. The ultrasonic transducer array as claimed in claim 59 wherein, the net-shape or near net shape fabrication technique comprises one or more of the following:
a gel casting process, which uses a precursor piezoelectric ceramic made from a gel; and
a viscous polymer processing (VPP) process, wherein the precursor piezoelectric ceramic is a paste.

61.-65. (canceled)

66. The ultrasonic transducer array as claimed in any of claims 49 to 65 wherein, one or more of the piezoelectric segments that form an array element has protrusions outwards towards other array elements in order to disrupt the propagation of waves laterally across the transducer array.
